(19) United States
(12) Patent Application Publication
(10) Pub. No.: US 2011/0096512 A1
(43) Pub. Date: Apr. 28, 2011

(54) PROXIMITY-ACTIVATED RELEASE FOR DOCKED ELECTRO-OPTICAL READER

(75) Inventors: Christopher KLICPERA, Westbury, NY (US); David YE, Baldwin, NY (US)

(73) Assignee: SYMBOL TECHNOLOGIES, INC., Holtsville, NY (US)

(21) Appl. No.: 12/606,353

(22) Filed: Oct. 27, 2009

(51) Int. Cl. H05K 7/00; G01C 21/02

(52) U.S. Cl. 361/747; 250/206.1

(57) ABSTRACT

A portable housing of a moving laser beam reader or an imaging reader is held by an operator in a handheld mode during electro-optical reading of symbols. A docking station supports the housing in a docked state when the housing is not in the handheld mode. At least one proximity sensor is supported by the housing and/or the docking station. The proximity sensor detects the operator's remoteness from the sensor to lock the housing to the docking station in the docked state, and detects the operator's proximity to the sensor to release the housing from the docking station.

### DESCRIPTION OF THE RELATED ART

Moving laser beam readers or laser scanners have long been used to electro-optically read one- and two-dimensional bar code symbols. The moving laser beam reader generally includes a housing, a laser for emitting a laser beam, a focusing lens assembly for focusing the laser beam to form a beam spot having a certain size at a focal plane in a range of working distances relative to the housing, a scan component for repetitively scanning the beam spot across a target symbol in a scan pattern, for example, a scan line or a series of scan lines, across the symbol multiple times per second, a photodetector for detecting light reflected and/or scattered from the symbol and for converting the detected light into an analog electrical signal, and signal processing circuitry including a digitizer for digitizing the analog signal and a microprocessor for decoding the digitized signal based upon a specific symbology used for the symbol.

Solid-state imaging systems or imaging readers have also been used to electro-optically read such symbols. The imaging reader includes a housing, a solid-state imager or sensor having an array of cells or photosensors, which correspond to image elements or pixels in a field of view of the imager, an illuminating light assembly for illuminating the field of view with illumination light from an illumination light source, e.g., a laser or one or more light emitting diodes (LEDs), and an imaging lens assembly for capturing return ambient and/or illumination light scattered and/or reflected from the symbol being imaged over a range of working distances. Such an imager may include a one- or two-dimensional charge coupled device (CCD) or a complementary metal oxide semiconductor (CMOS) device and associated circuits for producing electronic signals corresponding to a one- or two-dimensional array of pixel information over the field of view. Signal processing circuitry including a microprocessor processes the electronic signals to decode the symbol. An aiming light generator may also be provided in the housing for projecting an aiming light pattern or mark on the symbol prior to imaging.

Both types of readers can be portably operated in a handheld mode, in which an operator holds the respective housing in his or her hand during reading. Electrical power to the electronic components in the respective housing can be supplied via a cable connected to the housing, or via a rechargeable battery in the housing. When not in the handheld mode, the operator can park the housing in a docking station, which can serve myriad purposes, for example, as a hands-free reading station, or as a recharger for recharging the rechargeable battery, or as a convenient parking place to store the housing when not in active use.

As advantageous as such docking stations are, the portable housing can disengage therefrom in an environment subjected to vibration, sudden movement, or inversion. For increased retention, the art has proposed using spring-loaded or friction-fit mechanical latching mechanisms, which tend to wear and lose their effectiveness over time. The use of heavy duty springs for greater retention necessitates a larger pull-out force, and even more wear. The art has also proposed using locks requiring keys or security codes to unlock the housing. However, keys or security codes can be lost or forgotten.

Accordingly, there is a need for securely and affirmatively docking a handheld housing of a reader in a docking station with sufficient force to resist such disengagement, and for enabling ready release of the housing therefrom with little or no force.

### SUMMARY OF THE INVENTION

This invention relates to a system for electro-optically reading coded symbols, such as one- or two-dimensional bar code symbols. The reader includes a portable housing, preferably one having a handle held by an operator in a handheld mode during the reading, and an actuatable trigger mounted on the handle for initiating the reading when actuated by the operator. A docking station supports the housing in a docked state when the housing is not in the handheld mode, for example, when it is desired to recharge a rechargeable battery on-board the housing, or to conveniently park the housing when not in active use.

In one embodiment, the reader is a moving laser beam reader, which includes a laser for emitting the light as a laser beam, a scanner for sweeping the laser beam across the symbol as one scan line or a plurality of scan lines for reflection and scattering from the symbol as return light, and a photodetector for detecting the return light. In another embodiment, the reader is an imaging reader, which includes an illuminator for emitting the light as illumination light that illuminates the symbol, and a solid-state imager, such as a charge coupled device (CCD) or a complementary metal oxide semiconductor (CMOS) device, for detecting the return light. In each embodiment, a microprocessor or controller processes the return light to generate data corresponding to the symbol being read.

One feature of this invention resides, briefly stated in a retention mechanism that includes a proximity sensor supported by the housing and/or the docking station, for detecting the operator's remoteness or absence from the sensor to lock the housing to the docking station in the docked state and also for detecting the operator's proximity or presence to the sensor to release the housing from the docking station. Preferably, the proximity sensor is a capacitive sensor operative for sensing changes in an electromagnetic field exteriorly of the housing and/or the docking station based on the operator's interaction with the field and distance relative to the sensor.

The terms “proximity” or “presence” are intended to define a near or close-in range of distances along the field near the sensor. The near range extends from zero, i.e., the operator's hand touching the housing adjacent the sensor or the docking station adjacent the sensor, to a threshold distance away from the sensor. The terms “remoteness” or “absence” are intended to define a far or far-out range of distances along the field away from the sensor. The far range extends from the threshold distance to an even greater maximum distance away from the sensor. In a preferred embodiment, the threshold distance is about one foot, in which case, the housing is locked to the docking station when the operator is located more than one foot away from the sensor, and the housing is released from the docking station when the operator is located one foot or less away from the sensor. It will be expressly understood that this invention is not intended to be limited to a threshold distance of about one foot since other distances could be selected. The choice of threshold distance depends on the particular application. Advantageously, the housing is formed with a bore, and the mechanism includes a solenoid-actuated armature operatively connected to the proximity sensor and movable into the bore to lock the housing to the docking station, and movable out of the bore to release the housing from the docking station.

Hence, in accordance with this invention, the handheld housing of a reader is securely and affirmatively docked in the docking station with sufficient force to resist any disengagement caused by vibration, sudden movement, or inversion, and is readily released from the docking station with little or no force.

Another feature of this invention resides, briefly stated, in a method of electro-optically reading a symbol, which is performed by holding a housing by an operator in a handheld mode during electro-optical reading of the symbol, supporting the housing in a docking station in a docked state when the housing is not in the handheld mode, detecting the operator's remoteness from a proximity sensor supported by at least one of the housing and the docking station to lock the housing to the docking station in the docked state, and detecting the operator's proximity to the sensor with the proximity sensor to release the housing from the docking station.

The novel features which are considered as characteristic of the invention are set forth in particular in the appended claims. The invention itself, however, both as to its construction and its method of operation, together with additional objects and advantages thereof, will be best understood from the following description of specific embodiments when read in connection with the accompanying drawings.

### BRIEF DESCRIPTION OF THE DRAWINGS

FIG. 1 is a schematic diagram of a broken-away, handheld moving laser beam reader for electro-optically reading a coded symbol in accordance with one embodiment of the present invention;

FIG. 2 is a schematic diagram of a broken-away, handheld imaging reader for electro-optically reading a coded symbol in accordance with another embodiment of the present invention; and

FIG. 3 is a schematic, part-sectional view depicting the reader of FIG. 1 or FIG. 2 in a docking station in accordance with the present invention.

### DETAILED DESCRIPTION OF THE PREFERRED EMBODIMENTS

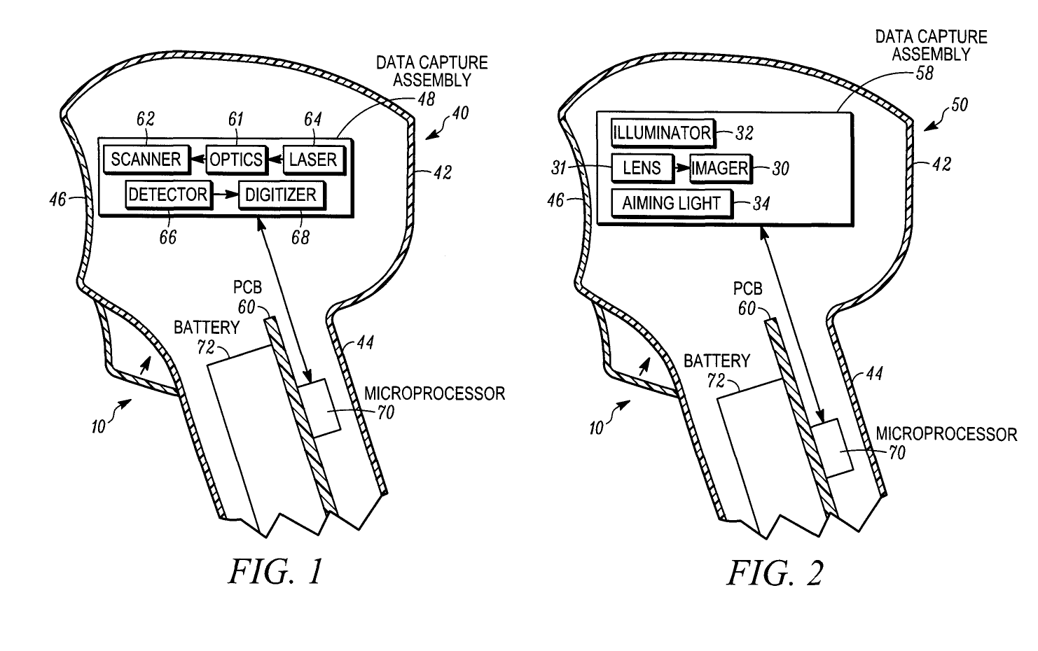

FIG. 1 depicts a moving laser beam reader 40 for electro-optically reading a target such as a coded symbol, that may use, and benefit from, the present invention. The beam reader 40 includes a scanner 62 in a portable, handheld housing 42 having a handle 44 on which a trigger 10 for initiating reading is mounted. The scanner 62 is operative for scanning an outgoing laser beam from a laser 64 and/or a field of view of a light detector or photodiode 66 in a scan pattern, typically comprised of one or more scan lines, multiple times per second, for example, one-hundred times per second, through a window 46 across the symbol for reflection or scattering therefrom as return light detected by the photodiode 66 during reading. The beam reader 40 also includes a focusing lens assembly or optics 61 for optically modifying the outgoing laser beam to have a large depth of field, and a digitizer 68 for converting an electrical analog signal generated by the detector 66 from the return light into a digital signal for subsequent decoding by a microprocessor or controller 70 into data indicative of the symbol being read. The aforementioned components, except for the controller 70, is depicted in FIG. 1 as a data capture assembly 48.

FIG. 2 depicts an imaging reader 50 for imaging targets, such as indicia or coded symbols to be electro-optically read, which may use, and benefit from, the present invention. The imaging reader 50 includes a one- or two-dimensional, solid-state imager 30, preferably a CCD or a CMOS array, mounted in the portable handheld housing 42 having the handle 44 on which the trigger 10 for initiating reading is mounted. The imager 30 has an array of image sensors operative, together with an imaging lens assembly 31, for capturing return light reflected and/or scattered from the symbol through the window 46 during the imaging to produce an electrical signal indicative of a captured image for subsequent decoding by the controller 70 into data indicative of the symbol being read.

The imaging reader 50 includes an illuminator 32 for illuminating the symbol during the imaging with illumination light directed from an illumination light source through the window 46. Thus, the return light may be derived from the illumination light and/or ambient light. The illumination light source comprises one or more light emitting diodes (LEDs) or a laser. An aiming light source 34 may also be provided for emitting an aiming beam and for projecting an aiming light pattern or mark on the symbol prior to imaging. The aforementioned components, except for the controller 70, is depicted in FIG. 2 as a data capture assembly 58.

In operation of the imaging reader 50, the controller 70 sends a command signal to drive the illuminator LEDs/laser 32, typically continuously, or sometimes periodically, during scanning, and energizes the imager 30 during an exposure time period of a frame to collect light from the symbol during a short time period, say 500 microseconds or less. A typical array needs about 33 milliseconds to read the entire target image and operates at a frame rate of about 30 frames per second. The array may have on the order of one million addressable image sensors.

Also shown in FIGS. 1-2 is a printed circuit board (PCB) 60 in the handle 44 on which the controller 70 and a rechargeable battery 72 are mounted. The controller 70 could be mounted on the same PCB as the data capture assemblies 48, 58. The rechargeable battery 72 supplies electrical power to all the electrical components in the readers 40, 50 in the handheld mode.

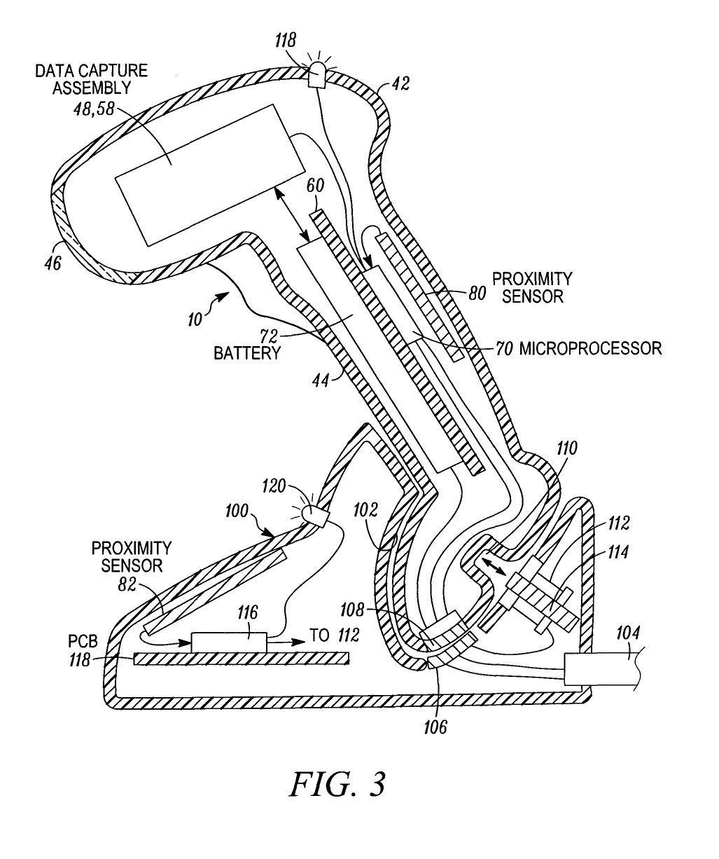

As shown in FIG. 3, reference numeral 100 identifies a docking station for supporting the housing 42 in a docked state when the housing 42 is not in the handheld mode, for example, when it is desired to recharge the rechargeable battery 72 on-board the housing 42, or to conveniently park the housing 42 when not in active use. Station 100 includes a compartment 102 for receiving and holding the housing 42. A cable 104 includes power conductors for supplying electrical power to recharge the battery 72, as well as data conductors for transmitting decoded data, control data, update data, etc. between the readers 40, 50 and a remote host (not illustrated). Electrical contacts 106 on the station 100 mate with electrical contacts 108 on the housing 42 to enable mutual electrical communication in the docked state.

In accordance with this invention, a retention mechanism includes a proximity sensor 80 supported by the housing 42 within the handle 44 and/or another proximity sensor 82 supported by the docking station 100, typically in a front region thereof. Each sensor 80, 82 is operative for detecting the operator's remoteness or absence from the respective sensor to lock the housing 42 to the docking station 100 in the docked state and also for detecting the operator's proximity or presence to the respective sensor to release the housing 42 from the docking station 100. Preferably, each proximity sensor is a capacitive sensor operative for sensing changes in an electromagnetic field exteriorly of the housing 42 and/or the docking station 100 based on the operator's interaction with the field and distance away from the respective sensor.

The terms “proximity” or “presence” are intended to define a near or close-in range of distances along the field near the respective sensor. The near range extends from zero, i.e., the operator's hand touching the handle 44 adjacent the sensor 80 or the front region of the docking station 100 adjacent the sensor 80, to a threshold distance away from the respective sensor. The terms “remoteness” or “absence” are intended to define a far or far-out range of distances along the field away from the respective sensor. The far range extends from the threshold distance to an even greater maximum distance away from the respective sensor. In a preferred embodiment, the threshold distance is about one foot, in which case, the housing 42 is locked to the docking station 100 when the operator, especially his or her hand, is located more than one foot away from the respective sensor, and the housing 42 is released from the docking station 100 when the operator, especially his or her hand is located one foot or less away from the sensor. Release is most strongly effected when the operator's hand grips the handle 44, in which case, the sensor 80 is activated. Release is also most strongly effected when the operator's hand touches the front region of the station 100, in which case, the sensor 82 is activated. It will be expressly understood that this invention is not intended to be limited to a threshold distance of about one foot since other distances could be selected. The choice of threshold distance depends on the particular application.

Advantageously, the housing 42 is formed with a bore 110, and an energizable solenoid 112 in the station 100 actuates a pin or armature 114 to move into the bore 110 to lock the housing 42 to the docking station 100, and to move out of the bore 110 to release the housing 42 from the docking station 100. Sensor 80 is connected to the controller 70 that, in turn, is electrically connected to the solenoid 112 via the electrical contacts 106, 108. The controller 70 generates an output control signal to energize the solenoid 112. Sensor 82 is connected to another controller 116 in the station 100 that, in turn, is electrically connected to the solenoid 112. The controller 116 generates an output control signal to energize the solenoid 112. Alternatively, the controller 116 could be omitted, and the sensor 82 is connected to the controller 70 via the electrical contacts 106, 108 and, in turn, to the solenoid 112.

It is further advantageous if the housing 42 has an indicator 118 and/or if the docking station 100 has an indicator 120, each indicator being operative for indicating when the housing is locked or released from the station 100. Each indicator is shown as an LED for visually indicating the locked or released state of the housing. Other types of indicators, including audio annunciators, could also be employed. Each LED has an illuminated state and a non-illuminated state, one of which visually indicates the locked state, and the other of which visually indicates the released state. Multiple LEDs, as well as different colors for the emitted light, could similarly be used.

It is still further advantageous if the trigger 10 is used as a manual override in case the housing remains in the locked state despite the operator's interaction with the proximity sensor. Thus, depression of the trigger while on the station could be detected by the controller 70 to generate an override signal to activate the solenoid.

Hence, in accordance with this invention, the handheld housing of a reader is securely and affirmatively docked in the docking station with sufficient force to resist any disengagement caused by vibration, sudden movement, or inversion, and is readily released from the docking station with little or no force.

It will be understood that each of the elements described above, or two or more together, also may find a useful application in other types of constructions differing from the types described above. For example, the retention mechanism need not be implemented by a single armature moving in and out of a single bore. A plurality of armatures and a corresponding plurality of bores could be used. Thus, a pair of collinear armatures could move in and out of collinear bores formed at opposite sides of the handle 44. Proximity sensors, other than of the capacitive type, could be used. Different housing configurations and station configurations could be employed. Different retention mechanisms are within the spirit of this invention.

While the invention has been illustrated and described as embodied in electro-optical systems having proximity sensors for locking and releasing portable readers to and from docking stations, it is not intended to be limited to the details shown, since various modifications and structural changes may be made without departing in any way from the spirit of the present invention. Although the preferred embodiments have been described with reference to exemplary handheld symbol readers, it will be appreciated by those skilled in the art that the docking retention mechanism and method described herein may be used with equal benefit for other types of electronic devices, e.g., mobile computers, telephones, music players, etc. Accordingly, this invention is not intended to be solely limited to use only with symbol readers.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention and, therefore, such adaptations should and are intended to be comprehended within the meaning and range of equivalence of the following claims.

What is claimed as new and desired to be protected by Letters Patent is set forth in the appended claims.

We claim:

1. An electro-optical symbol reading system, comprising:
a reader for electro-optically reading a symbol, including a housing held by an operator in a handheld mode during reading;
a docking station for supporting the housing in a docked state when the housing is not in the handheld mode; and
a mechanism including a proximity sensor supported by at least one of the housing and the docking station, for detecting the operator's remoteness from the sensor to lock the housing to the docking station in the docked state and for detecting the operator's proximity to the sensor to release the housing from the docking station.

2. The system of claim 1, wherein the housing has a handle held by the operator during the reading; and wherein the proximity sensor is supported by the handle.

3. The system of claim 1, wherein the proximity sensor is supported by the docking station.

4. The system of claim 1, wherein the housing has a bore; and wherein the mechanism includes a solenoid-actuated armature operatively connected to the proximity sensor and movable into the bore to lock the housing to the docking station, and movable out of the bore to release the housing from the docking station.

5. The system of claim 1, wherein the reader sweeps a laser beam across the symbol during the reading.

6. The system of claim 1, wherein the reader includes a solid-state imager for detecting return light from the symbol during the reading.

7. The system of claim 1, wherein the proximity sensor is a capacitive sensor for sensing changes in an electromagnetic field exteriorly of the at least one of the housing and the docking station based on the operator's interaction with the field and distance relative to the sensor.

8. A method of electro-optically reading symbols, comprising the steps of:
holding a housing by an operator in a handheld mode during electro-optical reading of a symbol;
supporting the housing in a docking station in a docked state when the housing is not in the handheld mode;
detecting the operator's remoteness from a proximity sensor supported by at least one of the housing and the docking station to lock the housing to the docking station in the docked state; and
detecting the operator's proximity to the sensor with the proximity sensor to release the housing from the docking station.

9. The method of claim 8, wherein the holding step is performed by gripping a handle on the housing during the reading; and supporting the proximity sensor by the handle.

10. The method of claim 8, and supporting the proximity sensor by the docking station.

11. The method of claim 8; and the step of forming the housing with a bore; and wherein the housing is locked to the docking station by moving an armature into the bore; and wherein the housing is released from the docking station by moving the armature out of the bore.

12. The method of claim 8, wherein the reading is performed by sweeping a laser beam across the symbol.

13. The method of claim 8, wherein the reading is performed by detecting return light from the symbol with a solid-state imager.

14. The method of claim 8, wherein the detecting steps are performed by sensing changes in an electromagnetic field exteriorly of the at least one of the housing and the docking station based on the operator's interaction with the field and distance relative to the sensor.

15. A docking system, comprising:
a housing held by an operator in a handheld mode;
docking means for supporting the housing in a docked state when the housing is not in the handheld mode; and
detecting means including a proximity sensor means supported by at least one of the housing and the docking means for detecting the operator's remoteness from the sensor means to lock the housing to the docking means in the docked state, and for detecting the operator's proximity to the sensor means to release the housing from the docking means.

16. The system of claim 15, wherein the housing has a handle held by the operator; and wherein the proximity sensor means is supported by the handle.

17. The system of claim 15, wherein the proximity sensor means is supported by the docking means.

18. The system of claim 15, wherein the housing has a bore; and wherein the detecting means includes an armature operatively connected to the proximity sensor means and movable into the bore to lock the housing to the docking means, and movable out of the bore to release the housing from the docking means.

19. The system of claim 15, wherein the proximity sensor means is operative for sensing changes in an electromagnetic field exteriorly of the at least one of the housing and the docking means based on the operator's interaction with the field and distance relative to the sensor means.

20. The system of claim 15, and means for indicating to the operator when the housing is locked and released relative to the docking means.
